(19) United States
(12) Patent Application Publication
(10) Pub. No.: US 2024/0215167 A1
(43) Pub. Date: Jun. 27, 2024

(54) TRANSISTOR PIN ALIGNMENT ASSEMBLY

(71) Applicant: Garrett Transportation I Inc, Torrance, CA (US)

(72) Inventor: Valeriy Fedorikhin, Redondo Beach, CA (US)

(73) Assignee: Garrett Transportation I Inc, Torrance, CA (US)

(21) Appl. No.: 18/145,066

(22) Filed: Dec. 22, 2022

(51) Int. Cl. H05K 1/18; H05K 3/34

(52) U.S. Cl. CPC H05K 1/18; H05K 3/3447; H01L 25/115; H05K 2201/10166; H05K 2201/10606; H05K 2201/10757; H05K 2201/10901

(57) ABSTRACT

An electric vehicle thermal management system for compressing a low pressure refrigerant with a centrifugal compressor to generate a high pressure refrigerant, determining a battery cooling condition, routing one of the low pressure refrigerant and the high pressure refrigerant to the heat exchanger in response to the battery cooling condition, regulating a transfer of heat between the refrigerant loop and the battery cooling loop in response to a temperature of the battery coolant within the battery cooling loop and the battery cooling condition, and regulating the transfer of heat between the battery coolant loop and a cabin coolant loop in response to the HVAC setting and a cabin coolant temperature within the cabin coolant loop.

### TECHNICAL FIELD

The present disclosure generally relates to automated printed circuit board manufacturing and, more particularly, relates to a three part component carrier for aligning transistor pins during automated assembly having a first pin alignment portion affixed to the printed circuit board, a second carrier portion for retaining the transistors, and a third portion for distributing insertion force over the transistor pins.

### BACKGROUND

Automated printed circuit board (PCB) assembly employs complex robotic system to place electronic components into PCBs and solder these components into place. Decreasing assembly time, reducing cost, increasing component density and minimizing damage or scrap during assembly are ever present goals in PCB assembly. As these PCBs become smaller and more complex, more sophisticated assembly methods and automation systems are required to address these goals. A problem associated with PCB assembly automation include positioning and loading of PCBs and components. PCBs and ever shrinking components are fragile and handling of these components must be done carefully to reduce damage during the assembly process. Each component must be properly aligned during placement and soldering or the entire assembly process as any damage generally requires the entire PCB to be scrapped.

One notoriously difficult component to handle during an automated PCB assembly process are power transistors. These power transistors, such as MOSFETS, typically have three or four long legs made of soft copper that must be inserted through tight holes in the PCB. These long copper legs are required to distance the transistor from the PCB for thermal management purposes. Typically individual transistors are less expensive than integrated modules and are more desirable when cost considerations are important. These individual transistors however often result in much higher assembly costs for the entire inverter than assembling a fewer number of larger integrated modules. The individual pins of each transistor all need to be aligned together and held together accurately enough to fit into the holes meant for them in the PCB. The holes in the PCB must be very small to insure good soldering and electrical connection. Typically, these pins have loose tolerances for pin location from the manufacturer which increases the complexity of the assembly. Thus, it is desirable to address these problems and to provide an accurate method and apparatus for aligning the transistor pins during the automated PCB assembly process. Other desirable features and characteristics of the present disclosure will become apparent from the subsequent detailed description and the appended claims, taken in conjunction with the accompanying drawings and this background discussion.

### BRIEF SUMMARY

In one embodiment, an electronic component alignment system including a carrier portion having a first side and a second side configured to receive an electronic component on the first side, wherein the electronic component includes a wire pin connection, and wherein the wire pin connection passes through a first hole in the carrier portion from the first side to the second side via a conical extrusion on the second side, a clamping portion configured to clamp the wire pin connection to the first side, and a pin alignment portion mechanically coupled to a printed circuit board having a conical extraction including a second hole at an apex of the conical extraction wherein the second hole is aligned with a through hole in the printed circuit board

In another embodiment, a method for aligning an electronic component pin to a circuit board through hole including applying an electronic component to a cavity in a first side of a carrier portion, wherein the electronic component includes a wire pin connection and wherein the wire pin connection passes through a first hole in the carrier portion from the first side to the second side via a conical extrusion on the second side, inserting a clamping portion to the first side to form a carrier assembly such that the electronic component is mechanically fixed to the first side, affixing an alignment portion to a printed circuit board, wherein the alignment portion includes a conical extraction having a guide hole at an apex of the conical extraction and wherein the guide hole is aligned with a through hole on the printed circuit board, affixing the alignment portion to the carrier portion such that the conical extrusion is positioned within the conical extraction and where the wire pin connection passes through the guide hole and through the through hole, and soldering the printed circuit board to the wire pin connection

Moreover, a printed circuit board alignment system including a carrier portion having a first side and a second side configured to receive MOSFET transistor on the first side, wherein the MOSFET transistor includes a plurality of wire pin connection leads, and wherein the a plurality of wire pin connection leads each pass through one of a plurality of carrier holes in the carrier portion from the first side to the second side via a triangular prism extrusion on the second side, a clamping portion configured to clamp the plurality of wire pin connection leads to the first side, and a pin alignment portion mechanically coupled to a printed circuit board having a triangular prism extraction including a plurality of alignment holes at an apex of the triangular prism extraction wherein each of the plurality of the alignment holes is aligned with a through hole in the printed circuit board.

The above advantage and other advantages and features of the present disclosure will be apparent from the following detailed description of the preferred embodiments when taken in connection with the accompanying drawings.

### BRIEF DESCRIPTION OF THE DRAWINGS

The present disclosure will hereinafter be described in conjunction with the following drawing figures, wherein like numerals denote like elements, and wherein:

FIG. 1 illustrates an exemplary transistor pin alignment assembly according to exemplary embodiments of the present disclosure;

FIG. 2 illustrates an exploded perspective view of an exemplary transistor pin alignment assembly according to exemplary embodiments of the present disclosure;

FIG. 3 illustrates, an exemplary method for transistor pin alignment according to exemplary embodiments of the present disclosure;

FIG. 4 illustrates an exemplary assembly of a carrier installed in a PCB enclosure according to exemplary embodiments of the present disclosure;

FIG. 5 illustrates an underside view of an exemplary pin alignment portion according to exemplary embodiments of the present disclosure; and

FIG. 6 illustrates an exemplary assembly of a PCB installation in a carrier and PCB enclosure according to exemplary embodiments of the present disclosure.

### DETAILED DESCRIPTION

The following detailed description is merely exemplary in nature and is not intended to limit the present disclosure or the application and uses of the present disclosure. Furthermore, there is no intention to be bound by any theory presented in the preceding background or the following detailed description.

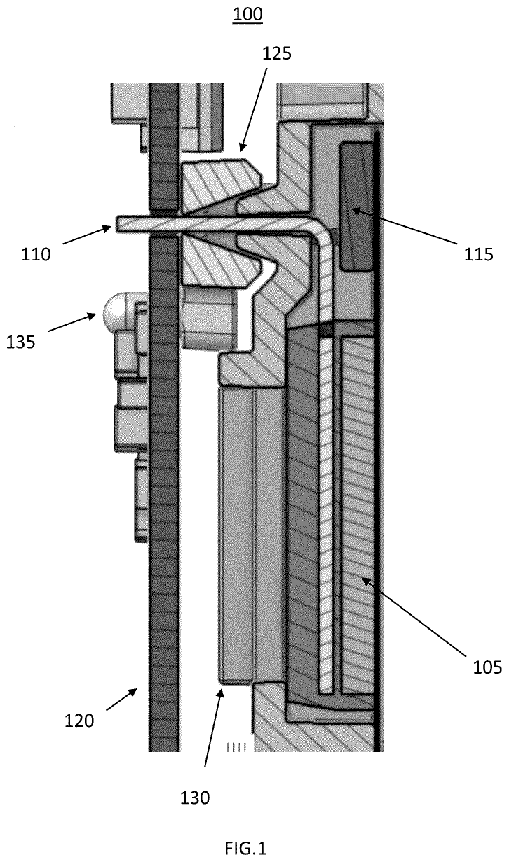

Turning now to FIG. 1, an exemplary transistor pin alignment assembly 100 is shown. The exemplary assembly 100 includes a carrier 130, a clamping portion 115 and a pin alignment portion 125. The exemplary assembly further includes a printed circuit board 120 and at least one transistor 105 with conductive pins 110. The exemplary transistor pin alignment assembly 100 is configured to retain one or more transistors 105 in a consistent fashion such that a printed circuit board (PCB) 120 can be positioned without damaging the transistor pins 110.

A problem exists in assembling certain through hole components, such as transistors, that have long metallic pins which may be crushed, bent, or improperly aligned during assembly. To address this problem, the exemplary assembly 100 is configured to hold the components and align the pins during assembly. In some exemplary embodiments, the carrier 130 is configured to retain and loosely align the individual transistors 105. The pins 110 of the transistors 105 are positioned through holes in the carrier 130. The clamping portion 115 is configured to be inserted into the carrier 130 to clamps the bottoms of the transistor pins so that the pins 110 don't deflect downwards as the PCB 120 is pressed onto the pins 110. The pin alignment portion 125 can be attached to the PCB 120 and is configured to facilitate the final pin alignment as the PCB 130 with the pin alignment portion 125 affixed is positioned over the pins 110.

In some exemplary embodiments, the pin alignment portion 125 can be configured as a funnel shaped guide affixed to the PCB 120. For example, the pin alignment portion 125 can include a cone shaped extraction around a through hole in the PCB 120 with an inverted cone extraction at the tip of the cone where the tip of the extracted cone aligns with the through hole. The outer surface of the pin alignment portion 125 can be configured to guide the carrier 130 with a cone shaped extrusion complementary to the cone shaped extraction guide on the carrier 130. The component pin 110 is assembled through a hole through the tip of the carrier cone in alignment with the through hole and the tip of the cone shaped extrusion.

In some exemplary embodiments, the transistors 105 are first placed in the carrier 130. Next, the clamping portion 115 is inserted into the carrier 130 thereby retaining the transistors 105 in the partial assembly 100. The partial assembly may then be inserted into an enclosure with the clamping portion 115 and the transistors 105 being positioned against an enclosure wall. The pin alignment portion 125 is then attached to the PCB 120 using one or more fasteners 135, such as screws, such that the inverted cones are aligned with the through holes on the PCB 120. During final assembly, the PCB 120 and pin alignment portion 125 portion of the assembly is then attached to the partial assembly such that the pins 110 are guided through the through holes of the PCB 120. The enclosure wall provides support to the partial assembly during attachment of the PCB 120 and pin alignment portion 125. The carrier also holds the components during assembly. A second part affixed to the carrier may apply opposing force on the pin along the through hole axis in response to force occurring during PCB installation.

The carrier 130 may be fabricated from a heat conductive material to act as a heatsink for the transistors 105. A thermally conductive material, such as a thermally conductive pad or a thermally conductive paste, may be applied between the transistor body and the carrier 130 to aid in thermal transfer between the transistor 130 and the carrier 130. The clamping portion 115 may be fabricated from a nonconductive material to prevent the pins 110 from shorting to the enclosure or the like.

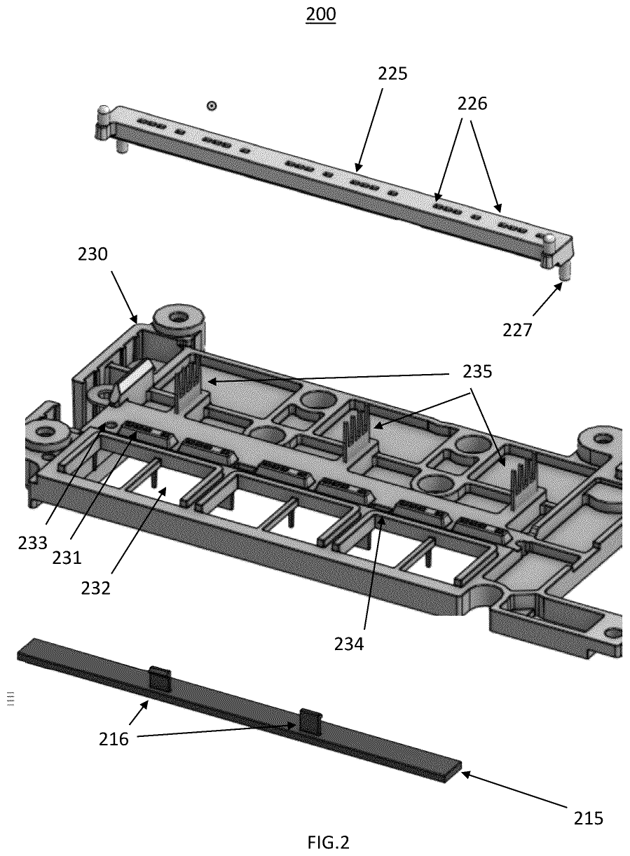

Referring now to FIG. 2, an exploded perspective view of an exemplary transistor pin alignment assembly 200 according to various embodiments is shown. The exemplary system 200 can include a carrier 230, a clamping portion 215 and a pin alignment portion 225 The exploded perspective view is illustrative of the various components and their relative orientations. The exemplary transistor pin alignment assembly 200 illustrated is configured to hold six MOSFET transistors, although any number or type of transistor may be used.

The exemplary carrier 230 can be a machined or molded part fabricated from a thermally conductive material which is also electrically conductive, such as aluminum. Alternatively, the carrier 230 can be fabricated from a thermally conductive and electrically insulative material. The exemplary carrier 230 has six location cavities 232 for receiving and restraining the body of a transistor. The pins of the transistors are inserted into the cone shaped extrusion 231 such that the pins extend towards the pin alignment portion 225. The carrier 230 may include one or more alignment holes 233 for receiving an alignment extrusion 227 on the pin alignment portion 225 such that the cone shaped extrusions are aligned with corresponding cone shaped extractions on the pin alignment portion 225. In some exemplary embodiments, the carrier 230 may be employed as an electrical ground for the PCB. The carrier 230 may include electrically conductive ground pins 235 to provide a current path between the PCB and the carrier 230. The carrier 230 can further be coupled to another electrical ground, such as an engine block, exhaust system, or vehicle frame to complete the grounding circuit.

The clamping portion 215 may next be affixed to the carrier 230 in a manner to retain the pins in the cone shaped extrusion. The clamping portion 215 may include spring retention hooks 216 for insertion into corresponding clamping holes 234 in the carrier 230. These spring retention clips 216 deflect to allow the hook to pass through when inserted into the clamping holes 234. Once the hooks are through the clamping holes 234, the spring force engages the hooks such that the clamping portion 215 is rigidly affixed to the carrier 230. The clamping portion 215 is configured to retain the transistors within the location cavities 232 during further assembly. This allows the carrier 230 to be positioned in any orientation while still retaining the transistors. In addition, during insertion of the PCB onto the transistor pin alignment assembly 200 a force is generated. The clamping portion 215 applies an opposing force to the transistor pins to prevent distortion of the pins during insertion into the PCB through holes.

The pin alignment portion 225 is mechanically affixed to the PCB and is configured to align the PCB with the carrier 230 and to provide a final alignment to the transistor pins with the PCB through holes. The pin alignment portion 225 can be affixed to the PCB with mechanical fasteners, such as screws that pass through corresponding holes in the PCB and a received by threaded cavities within the pin alignment portion 225. The pin alignment portion 225 can further include alignment extrusions 227 which align with alignment holes 233 in the carrier to provide an initial alignment of the pin alignment portion 225 with the carrier 230. The pin alignment portion 225 can include conical extractions configured to align with conical extrusions 231 on the carrier 230 to provide a final alignment of the transistor pins with the PCB through holes. During assembly, the transistor pins are aligned with the PCB through holes first via the alignment extrusions 227 and then by the conical extrusions 231. Once the pin alignment portion 225 with attached PCB is finally seated on the carrier 230, the transistor pins will have passed through the transistor pin alignment holes 226 at the bottom of the conical extractions and through the through holes in the PCB. At this point in the assembly, the transistor pins can then be soldered or otherwise conductively coupled to the PCB.

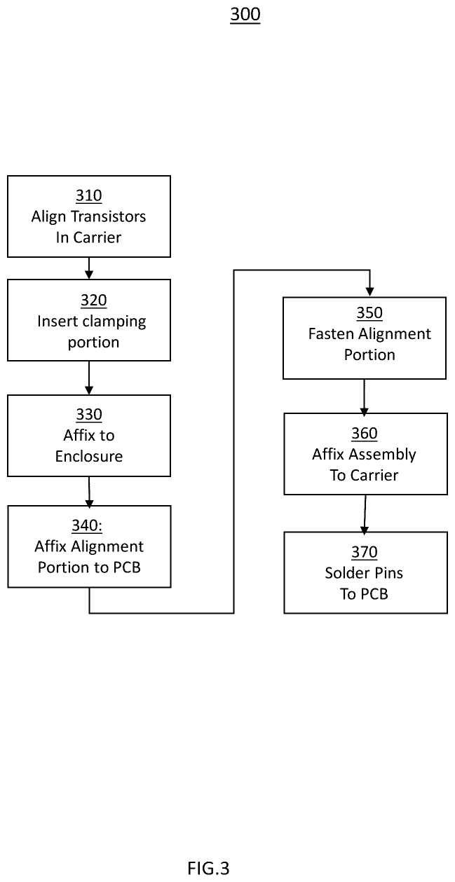

Turning now to FIG. 3, an exemplary method for transistor pin alignment 300 according to various embodiments is shown. The exemplary method 300 is operative to align transistor pins with PCB through holes to prevent damage to the pins, to ensure a reliable electrical connection after soldering and increase yield of the completed circuit boards.

The method is first operative to align 310 the transistors in a carrier. The transistors can be MOSFET type transistors with wire pin electrical connectors. The carrier can be a thermally conductive rigid structure having transistor location cavities for receiving and restraining the body of a transistor. There may be one or more transistor location cavities depending on the number of transistors to be coupled to the PCB. In some exemplary embodiments, the transistor body is placed in a transistor location cavity from a first side of the carrier with the pins of the transistor passing through one or more holes in the carrier to extend through to a second side opposite that of the first side.

The method is next operative to clamp 320 the transistor to the carrier using the clamping portion. The clamping portion may be inserted into the carrier from the first side to restrain the pins of the transistors such that the transistor is restrained into the carrier. The clamping portion is further configured to provide an opposing force to the pins of the transistor to prevent deformation of the pins during application of the PCB to the carrier. In some exemplary embodiments, a thickness of the clamping portion is equal to the distance between the transistor pins where they exit the transistor body and the uppermost surface of the transistor body. Thus, a flat surface against the uppermost surface of the transistor body and the clamping portion will result in a uniform force against both the transistor body and the clamping portion.

In some exemplary embodiments, the carrier is next affixed 330 to a PCB enclosure. The PCB enclosure is a protective enclosure to prevent damage to the PCB during operation. For example, for automotive applications, the PCB enclosure may be a sealed, metallic enclosure to prevent damage to the PCB from environmental conditions during operation of an automobile. The PCB enclosure may be thermally conductive for sinking heat from the PCB or components on the PCB, such as power transistors or the like. In some exemplary embodiments, the carrier is affixed to the PCB enclosure with the first side of the carrier being positioned towards an interior surface of the PCB enclosure using mechanical fasteners, such as screws or threaded bolts. Positioning the first side of the PCB enclosure towards the interior surface results in the uppermost surface of the transistor body and the clamping portion being positioned against a flat interior surface of the PCB enclosure. This flat interior surface of the PCB enclosure then provides support to the transistor body and the clamping portion during application of the PCB to the carrier.

The method is next operative to affix 340 the pin alignment portion to a first side of the PCB. The PCB can include location holes for aligning extrusions on the alignment portion to facilitate accurate positioning of the alignment portion. The alignment portion may then be mechanically fastened to the PCB using mechanical fasteners. For example, the alignment portion may be fastened to the PCB using screws from the second side of the PCB, opposite of the first side, through holes in the PCB into threaded cavities formed in the alignment portion. Alternatively, the alignment portion can include tab extrusions configured to be received in holes in the PCB during assembly. These tab extrusions can be twisted or deformed to secure the alignment assembly to the PCB and may be soldered to the PCB during soldering. These soldered tabs can be configured to provide improved electrical grounding to the PCB via the alignment portion, carrier and PCB enclosure.

After attachment of the alignment portion to the PCB, the PCB and alignment portion can be fastened 350 to the carrier. The PCB is positioned such that the alignment portion is oriented towards the carrier. The alignment portion can include guide extrusions for positioning within guide extractions in the carrier to align the alignment portion with the carrier. In addition, the carrier can include conical extrusions around the transistor pins for being received into corresponding conical extractions within the alignment portion. The apex of these conical extractions are aligned with the through holes in the PCB such that when the alignment portion is positioned on the carrier, the transistor pins are positioned within the through holes in the PCB without crushing the transistor pins. The clamping portion provides an opposing force to the force created by passing the transistor pins through the through holes.

The method is next operative to affix 360 the PCB and alignment portion assembly to carrier assembly in the enclosure using mechanical fasteners, such as screws or bolts, or may be retained using deformed metal tabs formed in the carrier assembly. These metal tabs can correspond to holes within the PCB and/or alignment portions and can be deformed, such as bent or twisted, after the PCB and alignment portion assembly has been finally positioned on the carrier. Finally, the method can be operative to solder 370 the transistor pins to the PCB. This soldering may be performed by a wave soldering process, reflow soldering process, or manually soldered. In addition, any fastening tab, grounding tab, or other components can be soldered at this point in the assembly process.

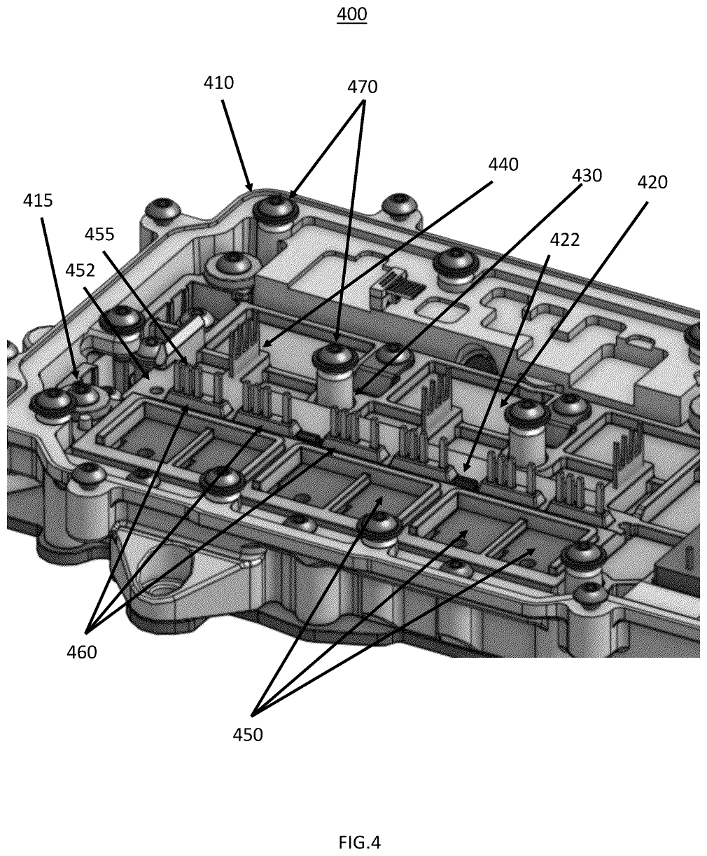

Turning now to FIG. 4, an exemplary assembly 400 of a carrier installed in a PCB enclosure according to various embodiments is shown. The exemplary assembly 400 is illustrative of a carrier 420 with a plurality of transistors 450 installed in a PCB enclosure 410. The transistor pins 455 are shown protruding from the conical extrusions 460 of the carrier 420. Various carrier fasteners 415 are shown for mechanically affixing the carrier to the PCB enclosure 420. Spring hooks of the clamping portion 422 are shown protruding from holes in the carrier 420 between the conical extrusions 460. In addition, mechanical fasteners 470 for affixing the PCB and alignment portion are shown. Grounding pins 440 are shown for electrically grounding the PCB when the PCB is installed.

Turning now to FIG. 5, an underside view of an exemplary pin alignment portion 500 according to various embodiments is shown. The conical extractions 510 are shown which correspond with the conical extrusions 460 of FIG. 4 are shown. These conical extrusions 510 with holes at the apex of the conical extraction are configured to align the transistor pins with the through holes in the PCB. The guide pin extrusions 520 for initially aligning with alignment portion 500 and PCB assembly with the carrier and PCB enclosure assembly are shown. These guide pin extrusions 520 are configured to be received in guide pin extractions 452 of FIG. 4 to provide an initial alignment of the carrier assembly with the PCB and alignment portion 500 assembly.

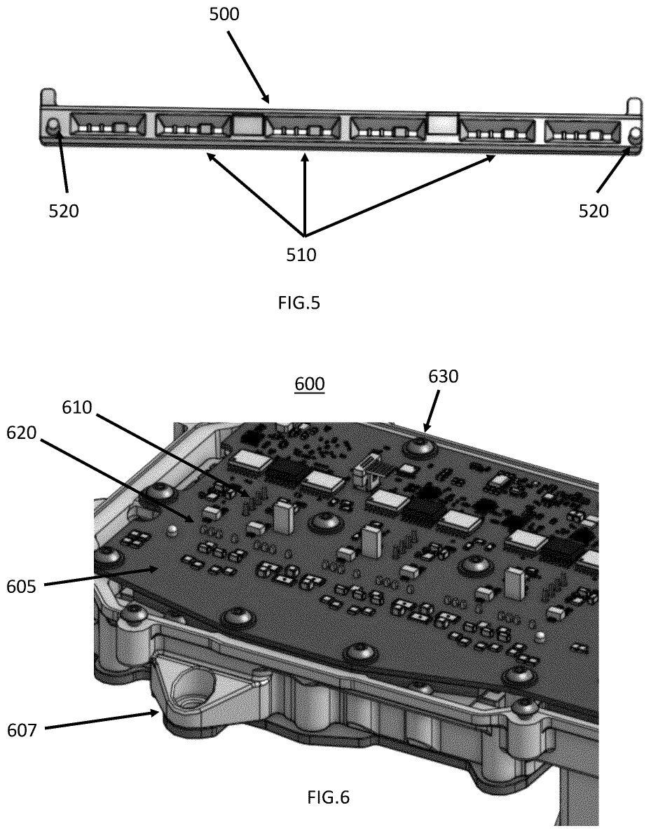

Turning now to FIG. 6, an exemplary assembly 600 of a PCB installation in a carrier and PCB enclosure according to various embodiments is shown. The PCB 605 is shown installed on the carrier assembly 607. The PCB 605 is affixed to the carrier assembly 607 via mechanical fasteners 630 though holes in the PCB 605. Transistor pins 620 are show protruding from the PCB 605 after being located within through holes in the PCB 605. Likewise, ground pins 610 are shown protruding from the PCB 605 after being located within through holes in the PCB 605. In some exemplary embodiments, this completed assembly 600 with PCB 605 installed can then be installed with a protective cover and/or installed in a related application or environment.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the present disclosure in any way. Rather, the foregoing detailed description will provide those skilled in the art with a convenient road map for implementing an exemplary embodiment of the present disclosure. It is understood that various changes may be made in the function and arrangement of elements described in an exemplary embodiment without departing from the scope of the present disclosure as set forth in the appended claims.

What is claimed is:

1. An electronic component alignment system comprising:
a carrier portion having a first side and a second side configured to receive an electronic component on the first side, wherein the electronic component includes a wire pin connection, and wherein the wire pin connection passes through a first hole in the carrier portion from the first side to the second side via a conical extrusion on the second side;
a clamping portion configured to clamp the wire pin connection to the first side ; and
a pin alignment portion mechanically coupled to a printed circuit board having a conical extraction including a second hole at an apex of the conical extraction wherein the second hole is aligned with a through hole in the printed circuit board.

2. The electronic component alignment system of claim 1 wherein the conical extrusion is guided by the conical extraction during attachment of the printed circuit board to the carrier portion.

3. The electronic component alignment system of claim 1 further including a product enclosure having an interior surface and wherein the carrier portion and the clamping portion are attached to the product enclosure with the first side and the clamping portion positioned against the interior surface.

4. The electronic component alignment system of claim 1 wherein the electronic component is a transistor and wherein a transistor body of the transistor is affixed to the first side of the carrier portion and wherein the wire pin connection includes a first segment parallel to the first side and a second segment perpendicular to the first side and wherein the second segment passes through the carrier portion and the conical extrusion.

5. The electronic component alignment system of claim 4 wherein the clamping portion is clamps the first segment of the wire pin connection to the first side of the carrier portion.

6. The electronic component alignment system of claim 1 wherein the electronic component is a MOSFET.

7. The electronic component alignment system of claim 1 wherein the wire pin connection is soldered to the printed circuit board after assembly of the pin alignment portion to the carrier portion.

8. The electronic component alignment system of claim 1 wherein the carrier portion further includes an electrically conductive pin for providing an electrical connection between the carrier portion and the printed circuit board.

9. The electronic component alignment system of claim 1 wherein the carrier portion further includes a guide extraction and wherein the pin alignment portion includes a guide extrusion for providing an initial alignment between the carrier portion and the pin alignment portion before the conical extrusion is engaged with the conical extraction.

10. The electronic component alignment system of claim 1 wherein the clamping portion is fabricated from an electrically nonconductive material and the carrier portion is fabricated from an electrically conductive material.

11. A method for aligning an electronic component pin to a through hole in a printed circuit board comprising:
applying an electronic component to a cavity in a first side of a carrier portion, wherein the electronic component includes a wire pin connection and wherein the wire pin connection passes through a first hole in the carrier portion from the first side to the second side via a conical extrusion on the second side;
inserting a clamping portion to the first side to form a carrier assembly such that the electronic component is mechanically fixed to the first side;
affixing an alignment portion to the printed circuit board, wherein the alignment portion includes a conical extraction having a guide hole at an apex of the conical extraction and wherein the guide hole is aligned with the through hole on the printed circuit board;
affixing the alignment portion to the carrier portion such that the conical extrusion is positioned within the conical extraction and where the wire pin connection passes through the guide hole and through the through hole; and
soldering the printed circuit board to the wire pin connection.

12. The method of claim 11 further including affixing the carrier assembly to a product enclosure having an interior surface and wherein the carrier assembly is attached to the product enclosure with the first side and the clamping portion positioned against the interior surface.

13. The method of claim 11 wherein the electronic component is a transistor and wherein a transistor body of the transistor is affixed to the first side of the carrier portion and wherein the wire pin connection includes a first segment parallel to the first side and a second segment perpendicular to the first side and wherein the second segment passes through the carrier portion and the conical extrusion.

14. The method of claim 13 wherein the clamping portion secures the first segment of the wire pin connection.

15. The method of claim 11 wherein the electronic component is a MOSFET and wherein the carrier portion is fabricated from a thermally conductive material.

16. The method of claim 11 wherein the wire pin connection is soldered to the printed circuit board.

17. The method of claim 11 wherein the clamping portion is formed from an electrically nonconductive material.

18. The method of claim 11 wherein the wire pin connection includes a plurality of wire pins, and wherein the printed circuit board includes a plurality of through holes corresponding to the plurality of wire pins.

19. A printed circuit board alignment system comprising:
a carrier portion having a first side and a second side configured to receive MOSFET transistor on the first side, wherein the MOSFET transistor includes a plurality of wire pin connection leads, and wherein the plurality of wire pin connection leads each pass through one of a plurality of carrier holes in the carrier portion from the first side to the second side via a triangular prism extrusion on the second side;
a clamping portion configured to clamp the plurality of wire pin connection leads to the first side; and
a pin alignment portion mechanically coupled to a printed circuit board having a triangular prism extraction including a plurality of alignment holes at an apex of the triangular prism extraction wherein each of the plurality of alignment holes is aligned with a through hole in the printed circuit board.

20. The printed circuit board alignment system of claim 19 wherein the clamping portion is configured to provide an opposing force to the plurality of wire pin connection leads.
